(19) United States
(12) Patent Application Publication
(10) Pub. No.: US 2026/0157184 A1
(43) Pub. Date: Jun. 4, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chun-Chong CHIEN, Taichung City (TW); Chih-Hsien CHIU, Taichung City (TW); Chia-Chen CHIAO, Taichung City (TW); Chao-Ya YANG, Taichung City (TW); Chien-Cheng LIN, Taichung City (TW); Chun-Sheng CHANG, Taichung City (TW); Hsin-Lung CHEN, Taichung City (TW)

(73) Assignee: SILICONWARE PRECISION INDUSTRIES CO., LTD., Taichung City (TW)

(21) Appl. No.: 19/306,361

(22) Filed: Aug. 21, 2025

(30) Foreign Application Priority Data
Dec. 2, 2024 (TW) 113146597

(51) Int. Cl. H01L 23/552; H01L 21/50; H01L 21/56; H01L 23/00; H01L 23/538; H01L 25/16

(52) U.S. Cl. CPC H10W 42/20; H10W 70/611; H10W 74/01; H10W 90/00; H10W 90/401; H10W 95/00; H10W 90/724

(57) ABSTRACT

An electronic package and a manufacturing method thereof are provided. A packaging module including a second electronic component is stacked on a circuit structure with a first electronic component via conductive pillars. The first electronic component and the second electronic component face each other. A shielding layer is disposed between the first electronic component and the second electronic component. Therefore, the requirements of reducing the layout area of the circuit structure and increasing the shielding effect can be met simultaneously.

### BACKGROUND

### 1. Technical Field

The present disclosure relates to a semiconductor packaging technology, and more particularly, to an electronic package with a shielding function and a manufacturing method thereof.

### 2. Description of Related Art

With the evolution of semiconductor technology, semiconductor products have been developed with different packaging product types. In order to improve electrical quality, many semiconductor products have shielding functions to prevent the occurrence of electromagnetic interference (EMI).

As shown in FIG. 1, in a conventional semiconductor package 1, in order to prevent EMI, a plurality of electronic components 11, 12 such as radio frequency and non-radio frequency chips are electrically connected to a packaging substrate 10, and a metal frame 17 is disposed on the packaging substrate 10 and located between the electronic components 11, 12. Then, a packaging layer 15 made of such as epoxy resin encapsulates each of the electronic components 11, 12 and the metal frame 17, and a plurality of solder balls 19 are placed on the lower side of the packaging substrate 10, so that the electronic components 11, 12 can be prevented from electromagnetically interfering with each other via the metal frame 17.

However, in the conventional semiconductor package 1, the electronic components 11, 12 are disposed on the same side of the packaging substrate 10, so that the packaging area of the packaging substrate 10 is very large. Moreover, when disposing on the circuit board of an end product, the conventional semiconductor package 1 needs to occupy lots of space on the circuit board of the end product, thereby making it difficult for the end product to meet the product requirements of being light, thin and compact in modern technology.

Therefore, how to overcome the aforementioned problems of the prior art has become an urgent issue to be solved.

### SUMMARY

In view of the aforementioned shortcomings of the prior art, the present disclosure provides an electronic package, which comprises: a circuit structure; a first electronic component disposed on the circuit structure; a packaging layer formed on the circuit structure and encapsulating the first electronic component; a packaging module stacked on and electrically connected to the circuit structure, wherein the packaging module includes a carrying structure and a second electronic component disposed on the carrying structure, the second electronic component corresponds to a position of the first electronic component, and the first electronic component and the second electronic component have an overlapping surface; and a shielding layer disposed between the first electronic component and the second electronic component.

The present disclosure further provides a method of manufacturing an electronic package, the method comprises: disposing a first electronic component on a circuit structure; forming a packaging layer on the circuit structure to encapsulate the first electronic component; stacking a packaging module on the circuit structure, and electrically connecting the packaging module to the circuit structure, wherein the packaging module includes a carrying structure and a second electronic component disposed on the carrying structure, the second electronic component corresponds to a position of the first electronic component, and the first electronic component and the second electronic component have an overlapping surface; and forming a shielding layer located between the first electronic component and the second electronic component.

In the aforementioned electronic package and method, the shielding layer is formed on the packaging layer to cover the first electronic component. For example, the shielding layer is in contact with the first electronic component. Alternatively, the shielding layer extends to edges of a surface of the packaging layer; even, the shielding layer extends to side surfaces of the packaging layer. The present disclosure further comprises forming another shielding layer on an outer surface of the packaging module, wherein the shielding layer is connected to the another shielding layer.

In the aforementioned electronic package and method, the shielding layer is formed on the packaging module to cover the second electronic component.

In the aforementioned electronic package and method, the present disclosure further comprises forming shielding elements on the circuit structure, wherein the shielding layer is grounded to the shielding elements.

In the aforementioned electronic package and method, the present disclosure further comprises forming shielding elements on the carrying structure, wherein the shielding layer is grounded to the shielding elements.

In the aforementioned electronic package and method, the present disclosure further comprises forming a plurality of conductive pillars on the circuit structure, wherein the packaging module is stacked on and electrically connected to the plurality of conductive pillars.

It can be seen from the above that, in the electronic package and the manufacturing method thereof of the present disclosure, the packaging module is stacked on the conductive pillars, and the shielding layer is disposed between the first electronic component and the second electronic component to provide the effect of shielding electromagnetic interference (EMI). Therefore, compared to the prior art, the electronic package of the present disclosure not only can reduce the layout area of the circuit structure, but also can increase the effect of shielding signal interference.

In addition, the manufacturing method of the present disclosure can be carried out by using only existing materials, existing processes and existing machines, so there is no need to develop new processes and new materials, and there is no need to purchase new machines; thus, the manufacturing method of the present disclosure does not incur a large amount of additional cost.

### BRIEF DESCRIPTION OF THE DRAWINGS

FIG. 1 is a schematic cross-sectional view showing a conventional semiconductor package.

FIG. 2A, FIG. 2B, FIG. 2C-1 and FIG. 2D are schematic cross-sectional views illustrating a manufacturing method of an electronic package of the present disclosure.

FIG. 2C-2 is a schematic top view of FIG. 2C-1.

FIG. 2E, FIG. 2F and FIG. 2G are schematic cross-sectional views showing other aspects of FIG. 2D.

FIG. 3A and FIG. 3B are schematic cross-sectional views showing other different embodiments of FIG. 2D.

FIG. 4 is a schematic cross-sectional view showing another embodiment of FIG. 2D.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

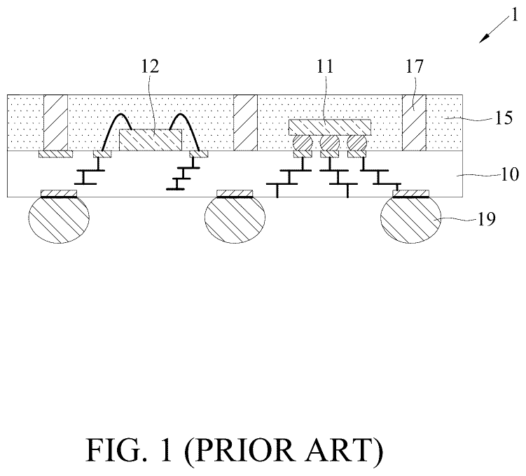

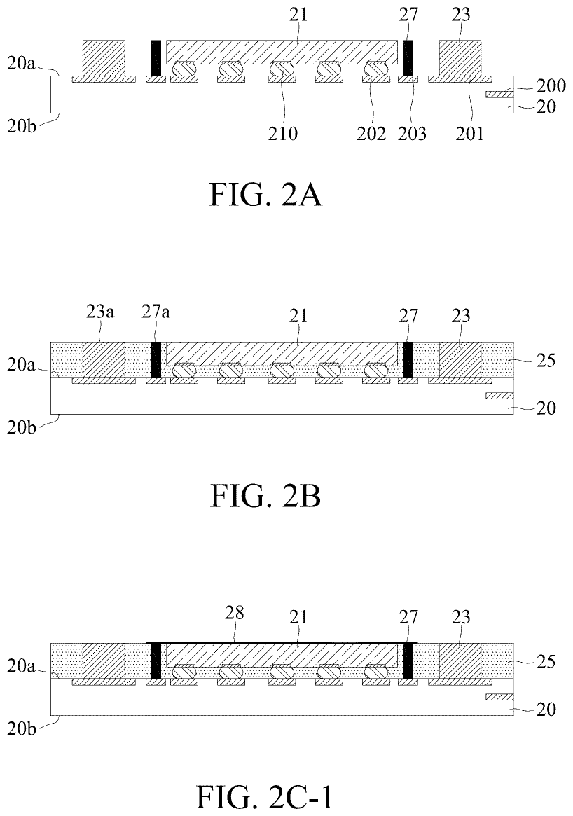

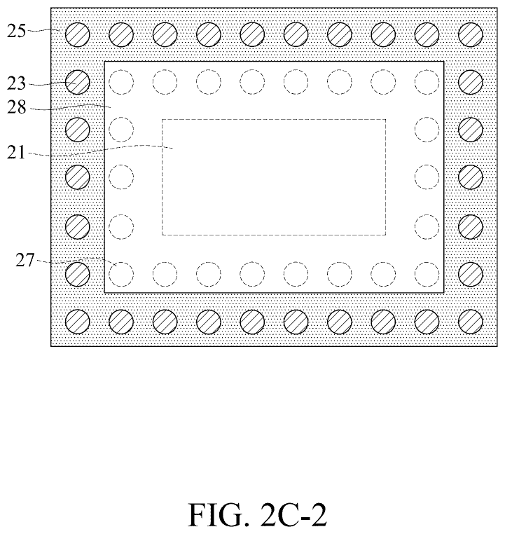

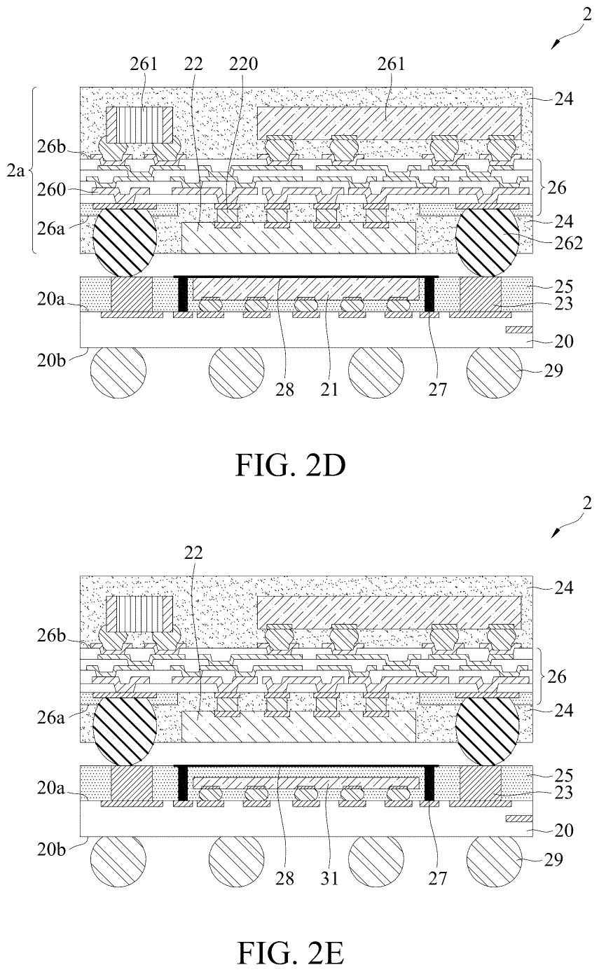

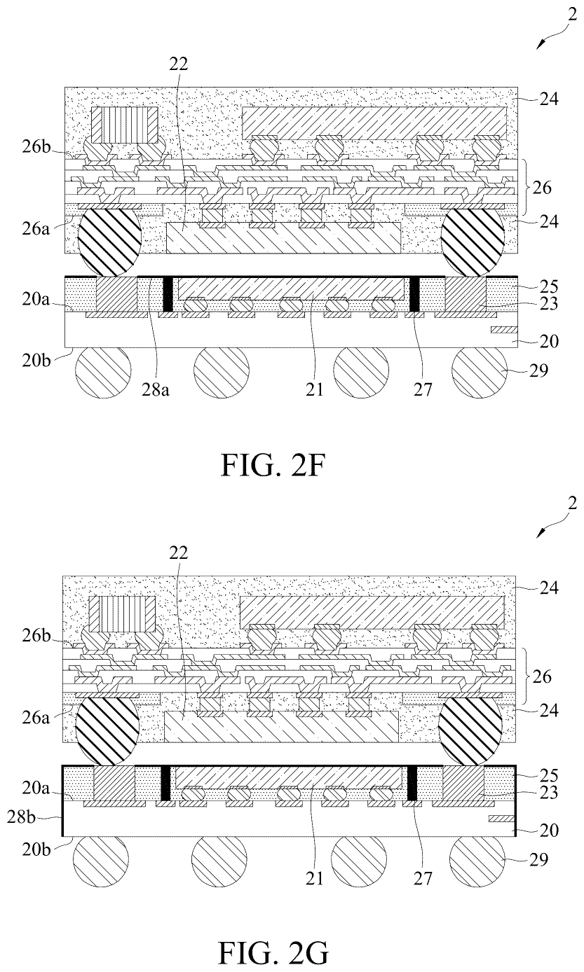

FIG. 2A, FIG. 2B, FIG. 2C-1 and FIG. 2D are schematic cross-sectional views illustrating a manufacturing method of an electronic package 2 of the present disclosure.

As shown in FIG. 2A, a circuit structure 20 is provided and has a first side 20a and a second side 20b opposite to the first side 20a, and at least one first electronic component 21, a plurality of conductive pillars 23 and at least one shielding element 27 are disposed on the first side 20a of the circuit structure 20.

The circuit structure 20 is, for example, a packaging substrate with a core layer or a coreless packaging substrate, and the circuit structure 20 has a plurality of circuit layers 200, such as fan-out redistribution layers (RDLs).

In one embodiment, the circuit layer 200 has a plurality of electrical contact pads 201, contacts 202 and ground pads 203.

It should be understood that the circuit structure 20 can also be other carrying units such as lead frame that can carry electronic components such as chips, but not limited to the above.

The first electronic component 21 is an active element, a passive element, or a combination of the active element and the passive element, wherein the active element is, for example, a semiconductor chip, and the passive element is, for example, a resistor, a capacitor, or an inductor.

In one embodiment, the first electronic component 21 is disposed on the contacts 202 in a flip-chip manner via a plurality of conductive bumps 210 made of such as solder material and is electrically connected to the circuit layer 200; alternatively, the first electronic component 21 can be electrically connected to the contacts 202 via a plurality of bonding wires (not shown) in a wire bonding manner; or, the first electronic component 21 may be directly in contact with the contacts 202. However, the way in which the first electronic component 21 is electrically connected to the circuit structure 20 is not limited to the above.

The conductive pillars 23 are used for external connection to other electronic devices, and the conductive pillars 23 have various types, such as bump combinations.

In one embodiment, the conductive pillars 23 are metal pillars such as copper pillars, and the conductive pillars 23 are bonded to the electrical contact pads 201 of the circuit layer 200 of the circuit structure 20 via solder material (not shown). It should be understood that solder balls may also be adopted as the conductive pillars 23, but not limited to the above.

The shielding elements 27 are disposed around the first electronic component 21, and the conductive pillars 23 are located outside the shielding elements 27.

In one embodiment, the shielding elements 27 are metal pillars formed by electroplating copper, and the shielding elements 27 are electrically connected (e.g., grounded) to the ground pads 203 of the circuit structure 20.

As shown in FIG. 2B, a packaging layer 25 is formed on the first side 20a of the circuit structure 20, so that the packaging layer 25 encapsulates the first electronic component 21, the shielding elements 27 and the conductive pillars 23, and parts of the first electronic component 21, the shielding elements 27 and the conductive pillars 23 are exposed from the packaging layer 25.

In one embodiment, the packaging layer 25 is made of insulating material, such as polyimide (PI), dry film, epoxy molding colloid, or epoxy molding compound, and the packaging layer 25 can be formed by lamination or molding.

Then, a flattening process can be performed, so that a surface of the packaging layer 25 is flush with an upper surface of the first electronic component 21, an end surface 27a of each of the shielding elements 27, and an end surface 23a of each of the conductive pillars 23, such that the shielding elements 27 and the conductive pillars 23 are exposed from the packaging layer 25. For example, grinding is used in the flattening process to remove part of the material of the packaging layer 25 and part of the material of each of the conductive pillars 23, even to remove part of the material of each of the shielding elements 27. It should be understood that the conductive pillars 23 or the shielding elements 27 can also be embedded in the packaging layer 25, so that the conductive pillars 23 or the shielding elements 27 can be exposed from the packaging layer 25 by openings.

As shown in FIG. 2C-1, a shielding layer 28 is formed on the packaging layer 25 and covers the first electronic component 21, wherein the shielding layer 28 is electrically connected (grounded) to the shielding elements 27 and is not electrically connected to the conductive pillars 23.

In one embodiment, the shielding layer 28 is a metal layer and is formed on the packaging layer 25 by electroplating, chemical plating, sputtering, or other coating methods, as shown in FIG. 2C-2. For example, the shielding layer 28 is only in contact with the shielding elements 27 and the first electronic component 21 and is not in contact with the conductive pillars 23. It should be understood that there are various types of the shielding layer 28, such as film form, and the present disclosure is not limited to as such.

As shown in FIG. 2D, a packaging module 2a is stacked on the conductive pillars 23, so that the electronic package 2 is attained, wherein the packaging module 2a includes a carrying structure 26, at least one second electronic component 22 disposed on the carrying structure 26, and an encapsulation layer 24 encapsulating the second electronic component 22.

The carrying structure 26 has a first surface 26a and a second surface 26b opposite to the first surface 26a, wherein the first surface 26a of the carrying structure 26 faces the first side 20a of the circuit structure 20.

In one embodiment, the carrying structure 26 is, for example, a packaging substrate with a core layer and a circuit structure, or the carrying structure 26 is a coreless circuit structure. The carrying structure 26 has a plurality of wiring layers 260, such as fan-out redistribution layers (RDLs).

Moreover, a plurality of conductive bumps 262 are arranged on the first surface 26a of the carrying structure 26 for stacking and bonding on the conductive pillars 23.

Furthermore, at least one functional component 261, such as an active element, a passive element, or a combination of the active element and the passive element, can be arranged on the second surface 26b according to requirements.

The second electronic component 22 is disposed on the first surface 26a of the carrying structure 26 to correspond to the position of the first electronic component 21, so that the first electronic component 21 and the second electronic component 22 are spaced apart with the shielding layer 28 therebetween.

In one embodiment, the second electronic component 22 is an active element, a passive element, or a combination of the active element and the passive element, wherein the active element is, for example, a semiconductor chip, and the passive element is, for example, a resistor, a capacitor, or an inductor. For example, the second electronic component 22 is disposed on the wiring layer 260 in a flip-chip manner via a plurality of conductive bumps 220 made of such as solder material; alternatively, the second electronic component 22 can be electrically connected to the wiring layer 260 via a plurality of bonding wires (not shown) in a wire bonding manner. However, the way in which the second electronic component 22 is electrically connected to the circuit structure 20 is not limited to the above.

The encapsulation layer 24 is formed on the first surface 26a and the second surface 26b of the carrying structure 26 to encapsulate the second electronic component 22 and the functional components 261.

In one embodiment, the encapsulation layer 24 is made of insulating material such as polyimide (PI), dry film, epoxy molding colloid, or epoxy molding compound. Thus, the encapsulation layer 24 can be formed by liquid compound, injection, lamination, or compression molding. It should be understood that the material for forming the packaging layer 25 and the material for forming the encapsulation layer 24 may be the same or different.

In subsequent processes, a plurality of conductive components 29 such as solder balls may be formed on the second side 20b of the circuit structure 20 for the electronic package 2 to be externally connected to an electronic device (not shown) such as a circuit board, a circuit structure, a packaging structure, or the like.

In addition, as shown in FIG. 2E, in another aspect, the shielding layer 28 may not be in contact with the first electronic component 31, that is, the first electronic component 31 is not exposed from the packaging layer 25; alternatively, as shown in FIG. 2F, in yet another aspect, the shielding layer 28a may extend to cover edges of an upper surface of the packaging layer 25, but the shielding layer 28a is still not in contact with the conductive pillars 23; even, as shown in FIG. 2G, in a further aspect, the shielding layer 28 may extend to side surfaces of the packaging layer 25 and side surfaces of the circuit structure 20, and the shielding layer 28 is not in contact with the conductive pillars 23.

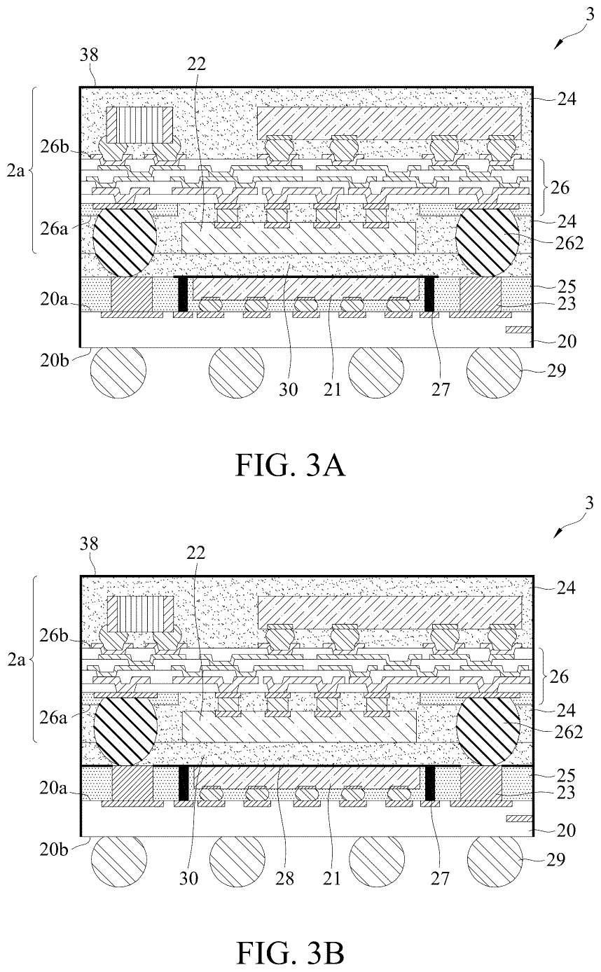

Moreover, in other embodiments, in an electronic package 3 shown in FIG. 3A, an insulating layer 30 such as underfill can be formed between the packaging module 2a and the packaging layer 25, such that the insulating layer 30 encapsulates the conductive bumps 262, and a shielding layer 38 can be formed on an outer surface of the packaging module 2a (or even the electronic package 3). It should be understood that, as shown in FIG. 3B, in another aspect, the shielding layer 38 can be further electrically connected to the shielding layer 28 formed on the packaging layer 25.

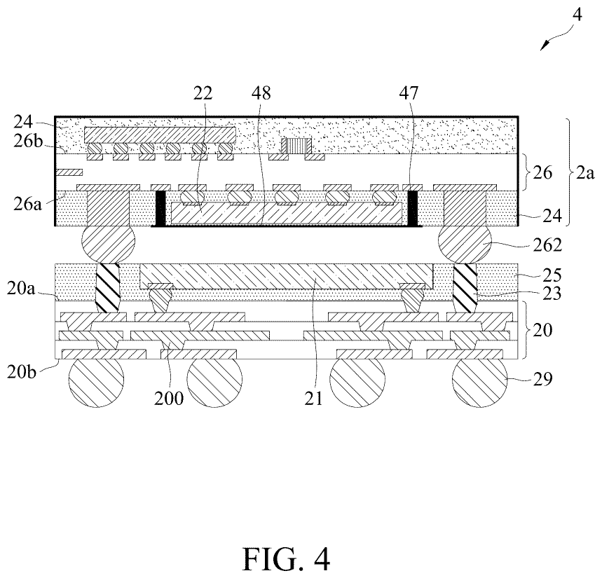

Additionally, in another embodiment, in an electronic package 4 shown in FIG. 4, a shielding layer 48 can also be formed on the second electronic component 22 of the packaging module 2a, the shielding elements 27 are arranged on the first surface 26a of the carrying structure 26, and the shielding layer 48 is electrically connected (grounded) to the shielding elements 27.

Therefore, the manufacturing method of the electronic package of the present disclosure mainly stacks the packaging module 2a on the circuit structure 20 (the conductive pillars 23), and disposes the shielding layer 28, 28a, 28b, 38, 48 between the first electronic component 21, 31 and the second electronic component 22 to provide the effect of shielding electromagnetic interference (EMI). Therefore, compared to the prior art, the electronic package 2, 3, 4 of the present disclosure not only can reduce the layout area of the first side 20a of the circuit structure 20, but also can increase the effect of shielding signal interference.

Moreover, the present disclosure can be carried out by using only existing materials, existing processes and existing machines, so there is no need to develop new processes and new materials, and there is no need to purchase new machines; thus, the manufacturing method of the present disclosure does not incur a large amount of additional cost.

The present disclosure also provides an electronic package 2, 3, 4, which comprises: a circuit structure 20, a first electronic component 21, 31, a plurality of conductive pillars 23, a packaging layer 25, a shielding layer 28, 28a, 28b, 48, and a packaging module 2a.

The first electronic component 21, 31 is disposed on the circuit structure 20 and electrically connected to the circuit structure 20.

The conductive pillars 23 are disposed on the circuit structure 20 and electrically connected to the circuit structure 20.

The packaging layer 25 is formed on the circuit structure 20 and encapsulates the first electronic component 21, 31 and the plurality of conductive pillars 23.

The packaging module 2a is stacked on the circuit structure 20 and electrically connected to the conductive pillars 23, wherein the packaging module 2a includes a carrying structure 26 and at least one second electronic component 22 disposed on the carrying structure 26, the second electronic component 22 corresponds to a position of the first electronic component 21, 31, and the first electronic component 21, 31 and the second electronic component 22 have an overlapping surface.

The shielding layer 28, 28a, 28b, 48 is disposed between the first electronic component 21, 31 and the second electronic component 22.

In one embodiment, the shielding layer 28, 28a, 28b is formed on the packaging layer 25 and covers the first electronic component 21, 31. For example, the shielding layer 28, 28a, 28b is in contact with the first electronic component 21. Alternatively, the shielding layer 28a extends to edges of an upper surface of the packaging layer 25; even, the shielding layer 28b extends to side surfaces of the packaging layer 25. Further, a shielding layer 38 is formed on an outer surface of the packaging module 2a and/or even on an outer surface of the electronic package 3, and the shielding layers 28, 38 can be electrically connected to each other.

In one embodiment, the shielding layer 48 is formed on the packaging module 2a and covers the second electronic component 22.

In one embodiment, the electronic package 2, 3 further comprises shielding elements 27 disposed on the circuit structure 20.

In one embodiment, the electronic package 4 further comprises shielding elements 47 disposed on the carrying structure 26.

To sum up, in the electronic package and the manufacturing method thereof of the present disclosure, the packaging module is stacked on the circuit structure, and the shielding layer is disposed between the first electronic component and the second electronic component to provide the effect of shielding electromagnetic interference. Therefore, the electronic package of the present disclosure not only can reduce the layout area of the circuit structure, but also can increase the effect of shielding signal interference.

In addition, the manufacturing method of the present disclosure can be carried out by using only existing materials, existing processes and existing machines, so there is no need to develop new processes and new materials, and there is no need to purchase new machines; thus, the manufacturing method of the present disclosure does not incur a large amount of additional cost.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a circuit structure;
a first electronic component disposed on the circuit structure;
a packaging layer formed on the circuit structure and encapsulating the first electronic component;
a packaging module stacked on and electrically connected to the circuit structure, wherein the packaging module includes a carrying structure and a second electronic component disposed on the carrying structure, the second electronic component corresponds to a position of the first electronic component, and the first electronic component and the second electronic component have an overlapping surface; and
a shielding layer disposed between the first electronic component and the second electronic component.

2. The electronic package of claim 1, wherein the shielding layer is formed on the packaging layer and covers the first electronic component.

3. The electronic package of claim 2, wherein the shielding layer is in contact with the first electronic component.

4. The electronic package of claim 2, wherein the shielding layer extends to edges of an upper surface of the packaging layer.

5. The electronic package of claim 2, wherein the shielding layer extends to side surfaces of the packaging layer.

6. The electronic package of claim 1, further comprising another shielding layer formed on an outer surface of the packaging module.

7. The electronic package of claim 6, wherein the shielding layer is connected to the another shielding layer.

8. The electronic package of claim 1, wherein the shielding layer is formed on the packaging module and covers the second electronic component.

9. The electronic package of claim 1, further comprising shielding elements disposed on the circuit structure, wherein the shielding layer is grounded to the shielding elements.

10. The electronic package of claim 1, further comprising shielding elements disposed on the carrying structure, wherein the shielding layer is grounded to the shielding elements.

11. The electronic package of claim 1, further comprising a plurality of conductive pillars disposed on the circuit structure, wherein the packaging module is stacked on and electrically connected to the plurality of conductive pillars.

12. A method of manufacturing an electronic package, comprising:
disposing a first electronic component on a circuit structure;
forming a packaging layer on the circuit structure to encapsulate the first electronic component;
stacking a packaging module on the circuit structure, and electrically connecting the packaging module to the circuit structure, wherein the packaging module includes a carrying structure and a second electronic component disposed on the carrying structure, the second electronic component corresponds to a position of the first electronic component, and the first electronic component and the second electronic component have an overlapping surface; and
forming a shielding layer located between the first electronic component and the second electronic component.

13. The method of claim 12, wherein the shielding layer is formed on the packaging layer to cover the first electronic component.

14. The method of claim 13, wherein the shielding layer is in contact with the first electronic component.

15. The method of claim 13, wherein the shielding layer extends to edges of a surface of the packaging layer.

16. The method of claim 13, wherein the shielding layer extends to side surfaces of the packaging layer.

17. The method of claim 12, further comprising forming another shielding layer on an outer surface of the packaging module.

18. The method of claim 17, wherein the shielding layer is connected to the another shielding layer.

19. The method of claim 12, wherein the shielding layer is formed on the packaging module to cover the second electronic component.

20. The method of claim 12, further comprising forming shielding elements on the circuit structure, wherein the shielding layer is grounded to the shielding elements.

21. The method of claim 12, further comprising forming shielding elements on the carrying structure, wherein the shielding layer is grounded to the shielding elements.

22. The method of claim 12, further comprising forming a plurality of conductive pillars on the circuit structure, wherein the packaging module is stacked on and electrically connected to the plurality of conductive pillars.
